(19) United States
(12) Patent Application Publication
(10) Pub. No.: US 2007/0259519 A1
(43) Pub. Date: Nov. 8, 2007

(54) INTERCONNECT METALLIZATION PROCESS WITH 100% OR GREATER STEP COVERAGE

(75) Inventors: Chih-Chao Yang, Poughkeepsie, NY (US); Kaushik Chanda, Fishkill, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/381,194

(22) Filed: May 2, 2006

(51) Int. Cl. H01L 21/4763

(52) U.S. Cl. 438/638; 257/E21.579

(57) ABSTRACT

An interconnect structure with a thicker barrier material coverage at the sidewalls of a feature as compared to the thickness of said barrier material at the feature bottom as well as a method of fabricating such an interconnect structure are provided. The interconnect structure of the present invention has improved technology extendibility for the semiconductor industry as compared with prior art interconnect structure in which the barrier material is formed by a conventional PVD process, a conventional ionized plasma deposition, CVD or ALD. In accordance with the present invention, an interconnect structure having a barrier material thickness at the feature sidewalls (wₜ) greater than the barrier material thickness at the feature bottom (hₜ) is provided. That is, the wₜ/hₜ ratio is equal to, or greater than, 100% in the inventive interconnect structure.

### FIELD OF THE INVENTION

The present invention relates to a semiconductor structure and a method of fabricating the same. More particularly, the present invention relates to an interconnect structure of the single or dual damascene type in which the step coverage of at least the barrier material within a feature provided in a dielectric material is equal to, or greater than, 100%. The present invention also relates to a method of fabricating such a semiconductor structure.

### BACKGROUND OF THE INVENTION

Generally, semiconductor devices include a plurality of circuits which form an integrated circuit fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring structures. The wiring structure typically includes copper, Cu, since Cu based interconnects provide higher speed signal transmission between large numbers of transistors on a complex semiconductor chip as compared with aluminum, Al, -based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “crosstalk”) are achieved in today's IC product chips by embedding the metal lines and metal vias (e.g., conductive features) in a dielectric material having a dielectric constant of less than silicon dioxide.

In current technologies, physical vapor deposited (PVD) TaN and PVD Cu seed layers are used as a Cu diffusion barrier and plating seed, respectively, for advanced interconnect applications. However, with decreasing critical dimension (CD), it is expected that PVD based deposition techniques will run into comformality and step coverage issues. These, in turn, will lead to fill issues at plating such as, for example, center and edge voids, which cause reliability concerns and yield degradation.

Because of poor step coverage from traditional metal neutral sputter depositions such as PVD, an ionized plasma deposition technique has been developed that dramatically improves the comformality limitation of the PVD process. This second generation of physical sputter deposition, which includes an ionized plasma, has been used in 90 nm and beyond advanced interconnect applications. In such a deposition process, the ratio of ionized metal, M⁺ to neutral metal, M is typically about 200 or greater. Although capable of improving the step coverage, this prior art technique deposits a thicker material at the feature bottom than at the sidewalls. Also, in order to meet the minimum amount of barrier material at the feature sidewalls, the prior art deposits too much barrier material than is required at the feature bottom. This increased liner volume fraction reduces the total available volume fraction for the conductive material, i.e., Cu, inside the feature, and degrades the total circuit performance.

As integrated circuit critical dimension (CD) continues to scale down, the thickness of the barrier material must decrease with decreasing CD in order to maintain equivalent circuit performance. However, the ionized plasma process described above always provides a thicker barrier material coverage at the feature bottom than at the feature sidewall. The ionized plasma deposition process described above thus always provides too much barrier material at the feature bottom, which is not desired for electrical resistance reduction on advanced semiconductor products.

As such, a new method is needed that is capable of providing an interconnect structure with thicker barrier coverage at the feature sidewall than at the feature bottom. It is noted that all prior art deposition methods including conventional PVD, ionized plasma PVD, chemical vapor deposition (CVD), and atomic layer deposition (ALD) result in a step coverage wherein the ratio of barrier material thickness on the sidewalls of the feature (wₜ) to the barrier material thickness at the feature bottom (hₜ), e.g., wₜ/hₜ, is less than 100%. A method is needed in which the wₜ/hₜ ratio of the barrier material thickness is equal to, or greater than, 100%. This is critical for technology extendibility.

### SUMMARY OF THE INVENTION

The present invention provides an interconnect structure with a thicker barrier material coverage at the sidewalls of a feature as compared to the thickness of said barrier material at the feature bottom as well as a method of fabricating such an interconnect structure. The interconnect structure of the present invention has improved technology extendibility for the semiconductor industry as compared with prior art interconnect structure in which the barrier material is formed by a conventional PVD process, a conventional ionized plasma deposition, CVD or ALD. In accordance with the present invention, an interconnect structure having a barrier material thickness at the feature sidewalls (wₜ) greater than the barrier material thickness at the feature bottom (hₜ) is provided. That is, the wₜ/hₜ ratio is equal to, or greater than, 100% in the inventive interconnect structure.

In general terms, the present invention provides a semiconductor structure including:
a dielectric material having at least one opening located therein, said at least one opening including sidewalls that extend and are in contact with a bottom wall portion;
a material stack comprising at least a diffusion barrier material located within said at least one opening covering said sidewalls and said bottom wall portion, wherein said material stack has a thickness at said sidewalls that is greater than a thickness at said bottom wall portion; and
a conductive material located on said material stack within said at least one opening.

In some embodiments of the present invention, the material stack also includes a metal seed layer in addition to the diffusion barrier material. In yet another embodiment of the present invention, an additional material stack (diffusion barrier/seed layer) is located on the sidewalls of the opening between the dielectric material and the material stack mentioned in the previous paragraph.

In addition to the general semiconductor structure described above, the invention also provides a method of fabricating the same. The method of the present invention, generally, comprises:
providing a dielectric material having at least one opening located therein, said at least one opening including sidewalls that extend and are in contact with a bottom wall portion;
forming a material stack comprising at least a diffusion barrier material within said at least one opening covering said sidewalls and said bottom wall portion, wherein said material stack has a thickness at said sidewalls that is greater than a thickness at said bottom wall portion; and
forming a conductive material on said material stack within said at least one opening.

In accordance with the present invention, the forming of the material stack whose thickness at the sidewalls of the opening is greater than the thickness at the bottom wall portion includes an ionization controlled metal plasma deposition process wherein the ratio of ionized metal to neutral metal is about 50 or less.

In some embodiments of the present invention, an additional material stack is provided at the sidewalls of the opening prior to forming the material stack having the thickness variation mentioned above. The additional material stack, which includes at least a diffusion barrier and, optionally, a seed layer, is formed by a conventional deposition process, followed by sputtering.

### BRIEF DESCRIPTION OF THE DRAWINGS

FIG. 1 is a pictorial representation (through a cross sectional view) illustrating an interconnect structure through initial stages of the inventive method wherein at least one opening is provided in a dielectric material.

FIG. 2 is a pictorial representation (through a cross sectional view) illustrating the structure of FIG. 1 after formation of a material stack comprising, from bottom to top, a barrier material and a seed layer utilizing the inventive ionization ratio controlled plasma deposition process.

FIG. 3 is a pictorial representation (through a cross sectional view) illustrating the structure of FIG. 2 after a conductive material is formed within the at least one opening.

FIGS. 4A-4D are pictorial representations (through cross sectional views) illustrating an alternative embodiment of the present invention.

FIGS. 5A and 5B are scanning electron micrographs of an interconnect structure formed via a conventional process and an interconnect structure formed utilizing the method of the present invention, respectively.

### DETAILED DESCRIPTION OF THE INVENTION

The present invention, which provides an interconnect structure having at least a barrier material with equal to, or greater than, 100% step coverage and a method of fabricating such an interconnect structure, will now be described in greater detail. The drawings of the present application, which are referred to herein below in greater detail, are provided for illustrative purposes and, as such, they are not drawn to scale.

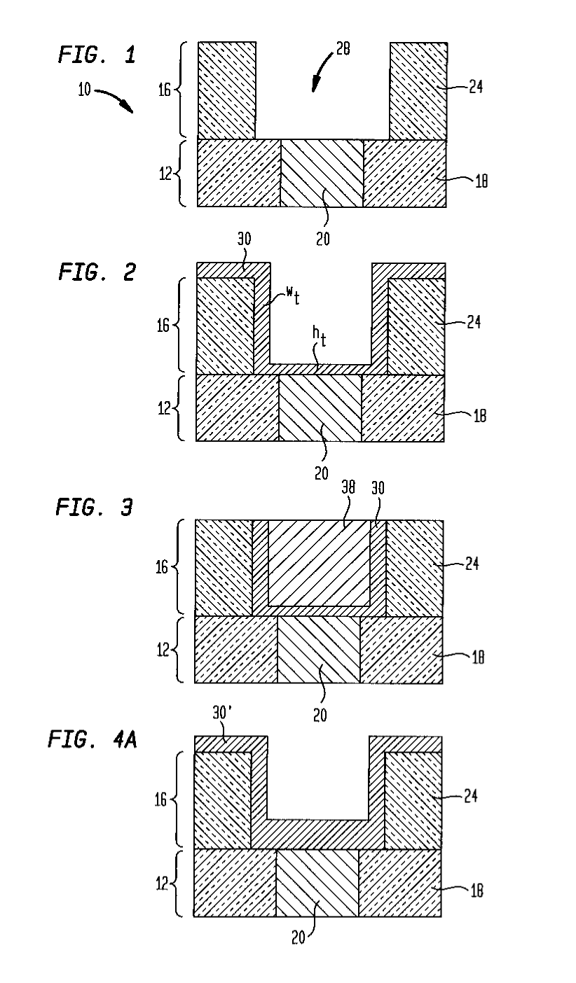

The process flow of the present invention begins with providing the initial interconnect structure 10 shown in FIG. 1. Specifically, the initial interconnect structure 10 shown in FIG. 1 comprises a multilevel interconnect including a lower interconnect level 12 and an upper interconnect level 16 that, in some embodiments, are separated in part by dielectric capping layer (not shown). The lower interconnect level 12, which may be located above a semiconductor substrate including one or more semiconductor devices, comprises a first dielectric material 18 having at least one conductive feature (i.e., conductive region) 20 that is separated from the first dielectric material 18 by a barrier layer (not shown). The upper interconnect level 16 comprises a second dielectric material 24 that has at least one opening 28 (i.e., feature) located therein. The at least one opening 28 may be a via opening, a line opening or a combination of a via opening and a line opening.

The initial interconnect structure 10 shown in FIG. 1 is made utilizing standard interconnect processing which is well known in the art. For example, the initial interconnect structure 10 can be formed by first applying the first dielectric material 18 to a surface of a substrate (not shown). The substrate, which is not shown, may comprise a semiconducting material, an insulating material, a conductive material or any combination thereof. When the substrate is comprised of a semiconducting material, any semiconductor such as Si, SiGe, SiGeC, SiC, Ge alloys, GaAs, InAs, InP and other III/V or II/VI compound semiconductors may be used. In addition to these listed types of semiconducting materials, the present invention also contemplates cases in which the semiconductor substrate is a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers. When the substrate comprises a semiconducting material, one or more semiconductor devices such as, for example, complementary metal oxide semiconductor (CMOS) devices can be fabricated thereon.

The first dielectric material 18 of the lower interconnect level 12 may comprise any interlevel or intralevel dielectric including inorganic dielectrics or organic dielectrics. The first dielectric material 18 may be porous or non-porous. Some examples of suitable dielectrics that can be used as the first dielectric material 18 include, but are not limited to: SiO₂, silsesquixoanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The first dielectric material 18 typically has a dielectric constant that is about 4.0 or less, with a dielectric constant of about 2.8 or less being even more typical. These dielectrics generally have a lower parasitic crosstalk as compared with dielectric materials that have a higher dielectric constant than 4.0. The thickness of the first dielectric material 18 may vary depending upon the dielectric material used as well as the exact number of dielectrics within the lower interconnect level 12. Typically, and for normal interconnect structures, the first dielectric material 18 has a thickness from about 200 to about 450 nm.

The lower interconnect level 12 also has at least one conductive feature 20 that is embedded in (i.e., located within) the first dielectric material 18. The conductive feature 20 comprises a conductive region that is separated from the first dielectric material 18 by a diffusion barrier layer (not shown). The conductive feature 20 is formed by lithography (i.e., applying a photoresist to the surface of the first dielectric material 18, exposing the photoresist to a desired pattern of radiation, and developing the exposed resist utilizing a conventional resist developer), etching (dry etching or wet etching) an opening in the first dielectric material 18 and filling the etched region with the diffusion barrier layer (not shown) and then with a conductive material forming the conductive region. The diffusion barrier layer, which may comprise Ta, TaN, Ti, TiN, Ru, RuN, W, WN or any other material that can serve as a barrier to prevent conductive material from diffusing there through, is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating.

The thickness of the diffusion barrier layer (not shown) may vary depending on the exact means of the deposition process as well as the material employed. Typically, the barrier layer has a thickness from about 4 to about 40 nm, with a thickness from about 7 to about 20 nm being more typical.

It is noted that the diffusion barrier layer within the conductive feature 20 can also be formed utilizing the process of the present invention such that the barrier material thickness on the sidewalls is greater than the barrier material thickness on the bottom wall.

Following the diffusion barrier layer formation, the remaining region of the opening within the first dielectric material 18 is filled with a conductive material forming the conductive feature 20. The conductive material used in forming the conductive feature 20 includes, for example, polySi, a conductive metal, an alloy comprising at least one conductive metal, a conductive metal silicide or combinations thereof. Preferably, the conductive material that is used in forming the conductive feature 20 is a conductive metal such as Cu, W or Al, with Cu or a Cu alloy (such as AlCu) being highly preferred in the present invention. The conductive material is filled into the remaining opening in the first dielectric material 18 utilizing a conventional deposition process including, but not limited to: CVD, PECVD, sputtering, chemical solution deposition or plating. After deposition, a conventional planarization process such as, for example, chemical mechanical polishing (CMP) can be used to provide a structure in which the diffusion barrier layer and the conductive feature 20 each have an upper surface that is substantially coplanar with the upper surface of the first dielectric material 18.

In some embodiments of the present invention, a dielectric capping layer (not shown) is formed on the surface of the lower interconnect level 12 utilizing a conventional deposition process such as, for example, CVD, PECVD, chemical solution deposition, or evaporation. The dielectric capping layer, which is optional in the present invention, comprises any suitable dielectric capping material such as, for example, SiC, Si₄NH₃, SiO₂, a carbon doped oxide, a nitrogen and hydrogen doped silicon carbide SiC(N,H) or multilayers thereof. The thickness of the capping layer may vary depending on the technique used to form the same as well as the material make-up of the layer. Typically, the capping layer has a thickness from about 15 to about 55 nm, with a thickness from about 25 to about 45 nm being more typical.

Next, the upper interconnect level 16 is formed by applying the second dielectric material 24 to the upper exposed surface of the capping layer, if present, or atop the lower interconnect level 12. The second dielectric material 24 may comprise the same or different, preferably the same, dielectric material as that of the first dielectric material 18 of the lower interconnect level 12. The processing techniques and thickness ranges for the first dielectric material 18 are also applicable here for the second dielectric material 24. Next, at least one opening 28 is formed into the second dielectric material 24 utilizing lithography, as described above, and etching. The etching may comprise a dry etching process, a wet chemical etching process or a combination thereof. The term “dry etching” is used herein to denote an etching technique such as reactive ion etching, ion beam etching, plasma etching or laser ablation. In some embodiments, this etching step also removes a portion of the dielectric capping layer that is located atop the conductive feature 20 in order to make electrical contact between interconnect level 12 and interconnect level 16.

Next, and as illustrated in FIG. 2, a material stack 30 comprising, from bottom to top, a diffusion barrier material and a seed layer is formed within the at least one opening 28 as well as on the upper exposed surface of the second dielectric material 24. As shown, the material stack 30 is formed on the sidewalls of the opening 28 as well as a bottom portion thereof, the bottom portion of the opening exposes the conductive feature 20 and portions of the first dielectric material 18.

As shown, the material stack 30 has a thickness along the sidewalls (wₜ) which is thicker than the thickness along the bottom portion of the opening (hₜ). In accordance with the present invention, the wt to ht ratio is equal to, or greater than, 100%, typically greater than 120%.

It is noted that the material stack 30 does not need to include a metal seed layer. Thus, the metal seed layer is optional, but is typically used when a conductive metal is to be subsequently formed into the at least one opening 28.

The diffusion barrier material of material stack 30 may comprise Ta, TaN, Ti, TiN, Ru, RuN, RuTa, RuTaN, W, WN or any other material that can serve as a barrier to prevent a conductive material from diffusing there through. Combinations of these materials are also contemplated forming a multilayered stacked diffusion barrier. The diffusion barrier material has a greater thickness on the sidewalls of the opening than at the bottom portion thereof. Typically, the thickness of the diffusion barrier along the sidewalls is from about 4 to about 40 nm, with a thickness from about 7 to about 20 nm being even more typical. The thickness of the diffusion barrier material along the bottom portion of the opening is typically from about 3 to about 30 nm, with a thickness from about 6 to about 17 nm being even more typical.

As indicated above, the material stack 30 may optionally include a metal seed layer. Although optional, it is preferred to include a metal seed layer within the material stack 30 to aid in growth of the conductive material. This is especially the case when a conductive metal or metal alloy is to be subsequently formed within the at least one opening. Ru, Cu and Ir are some examples of metal seed layers that can be used in the present invention. When present, the metal seed layer may comprise a conductive metal or metal alloy such as that used in forming the conductive material 38 to be described in greater detail herein below. Typically, and when the conductive material 38 comprises Cu, the metal seed layer comprises Cu, CuAl, CuIr, CuTa, CuRh, TaRu, or other alloys of Cu, i.e., Cu-containing alloys. The thickness of the metal seed layer may vary and it is within ranges that are well known to those skilled in the art. Typically, the metal seed layer has a thickness from about 2 to about 80 nm. It is again noted that the thickness of the metal seed layer along the sidewalls of the opening is also greater than along the bottom portion of the opening.

Unlike prior art techniques wherein a conventional PVP, ionized plasma PVP, CVD or ALD process is used in forming the diffusion barrier/seed layer stack, the present invention utilizes an ionization ratio controlled plasma deposition process. In such a process, the ratio of ionized metal species M⁺ to neutral metal M is about 50 or less, with a ratio of M⁺ to M of 30 or less being even more preferred. Because the ratio of ionized metal to neutral metal is controlled in the present invention, the metal deposition rate difference between the feature bottom and the sidewall is less than conventional ionization processes.

The ionization ratio controlled plasma deposition process of the present invention is performed utilizing a conventional ionization plasma deposition apparatus. In the present invention, the ratio of ionized metal to neutral metal generated within the apparatus is controlled by adjusting at least one of the AC bias, the DC power, or the process pressure. Any combination of these parameters can also be adjusted to control the ionized metal to neutral metal ratio within the ranges mentioned above. When the DC power is selected to control the ratio of ionized metal to neutral metal, the DC power is reduced to a value of less than 15, preferably less than 10, kW. When the AC bias is selected to control the ratio of the ionized metal to neutral metal, the AC power is reduced to a value below 1000, preferably below 500, W. When the process pressure is selected to achieve the controlled M⁺ to M ratio, the process pressure is set to a value above 10, preferably above 20, mT.

Although not shown in the drawings of the present invention, further diffusion barrier/seed layers can be formed after the initial formation of the material stack 30. The further diffusion/seed layers can be formed utilizing the ionization ratio controlled process mentioned above.

Next, and as shown in FIG. 3, an interconnect conductive material 38 is formed within the at least one opening including the material stack 30. The interconnect conductive material 38 may comprise the same or different, preferably the same, conductive material as that of the conductive feature 20. Preferably, Cu, Al, W or alloys thereof are used, with Cu or AlCu being most preferred. The conductive material 38 is formed utilizing the same deposition processing as described above in forming the conductive feature 20 and following deposition of the conductive material, the structure is subjected to planarization. The planarization process removes the material stack 30 and conductive material 38 that are present above the upper horizontal surface of the upper interconnect level 16 providing the structure shown in FIG. 3.

The structure shown in FIG. 3 represents one possible embodiment of the present invention in which a closed-bottom structure is formed. In a closed-bottom structure, the material stack 30 is present on portions of conductive features 20. Open-bottom and anchored-bottom structure are also possible. The opened-bottom structure is formed by removing the material stack 30 from the bottom of the opening utilizing ion bombardment or another like directional etching process prior to deposition of the other elements of the upper interconnect level. The anchored-bottom structure is formed by first etching a recess into the conductive feature 20 utilizing a selective etching process and creating a gouging feature.

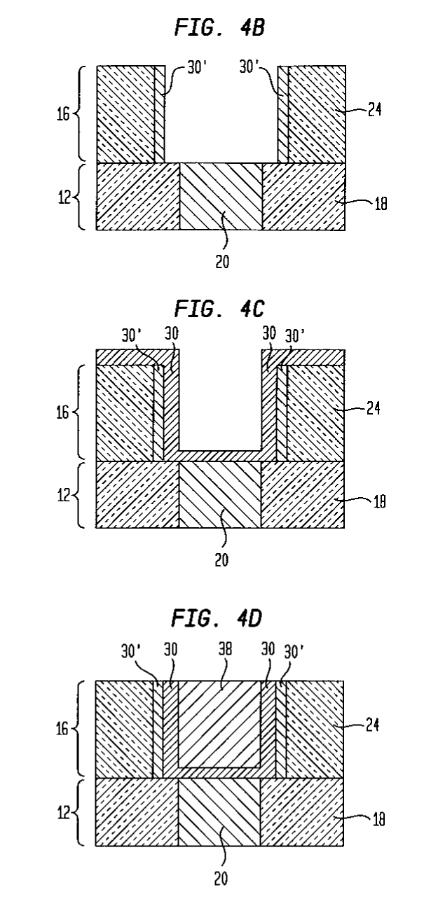

FIGS. 4A-4D illustrates another embodiment of the present invention in which the initial interconnect structure 10 as shown in FIG. 1 is first provided as described above. After providing the initial interconnect structure 10 shown in FIG. 1 a material stack 30′ including at least a diffusion barrier material and optionally a metal seed layer is provided utilizing a conventional deposition process. The resultant structure that is formed is shown, for example, in FIG. 4A.

Atomic layer deposition (ALD), chemical vapor deposition (CVD), plasma enhanced chemical vapor deposition (PECVD), physical vapor deposition (PVD), ionized plasma deposition, sputtering, chemical solution deposition, or plating can be used in forming the material stack 30′. In this embodiment, the thickness of the material stack 30′ at the feature bottom is greater than the thickness of the material stack 30′ at the feature sidewall. Thus, the ratio of wₜ to hₜ for material stack 30′ is less than 100%.

Following the formation of the material stack 30′, the structure shown in FIG. 4A is then subjected to a sputtering process which removes the material stack 30 from the bottom of the opening exposing the underlying conductive feature 20. The resultant structure during the sputtering process is shown, for example, in FIG. 4B. It is observed that this sputtering process also removes material stack 30′ that is located on the horizontal surface of the upper interconnect level 16. The sputtering process is performed utilizing Ar, He, Ne, Xe, N₂, H₂, NH₃, N₂H₂ or mixtures thereof. Typically, Ar is used as the sputtering gas. The conditions for this sputtering process are well known to those skilled in the art.

FIG. 4C shows the structure that is formed after forming material stack 30 utilizing the ionization ratio controlled process described above. Note that the feature sidewalls include material stack 30′ as well as material stack 30. Although not shown in the drawings of the present invention, further diffusion barrier/seed layers can be formed after the initial formation of the material stack 30. The further diffusion/seed layers can be formed utilizing the ionization ratio controlled process mentioned above.

FIG. 4D shows the structure after conductive material 38 fill and planarization. Open-bottom and anchored-bottom structures are also contemplated.

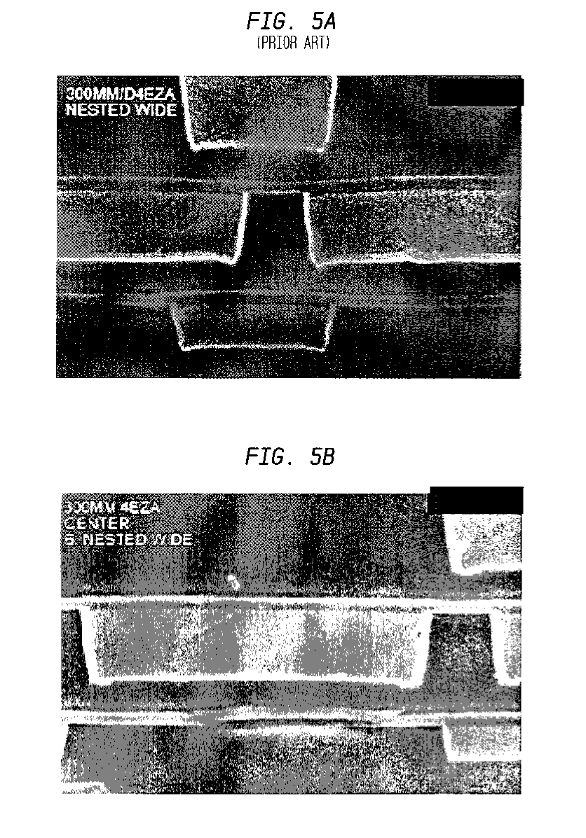

Reference is now made to FIGS. 5A and 5B which are scanning electron micrographs (SEMs) of an interconnect structure formed via a conventional process and an interconnect structure formed utilizing the method of the present invention, respectively. The SEMS clearly show that the inventive interconnect structure, as shown in FIG. 5B, has a material stack (e.g., diffusion barrier/seed layer) whose thickness is greater at the feature sidewall as compared to the feature bottom wall, while in the prior art structure, the opposite is observed. That is, in the prior art structure shown in FIG. 5A, the thickness of the material stack (e.g., diffusion barrier/seed layer) at the feature bottom is greater than that along the feature sidewall.

As such, the inventive method described herein above provides a technique for fabricating an interconnect structure that has equal to, or greater than, 100% step coverage (i.e., sidewall thickness greater than bottom thickness) which is not achieved utilizing prior art processes.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
a dielectric material having at least one opening located therein, said at least one opening including sidewalls that extend and are in contact with a bottom wall portion;
a material stack comprising at least a diffusion barrier material located within said at least one opening covering said sidewalls and said bottom wall portion, wherein said material stack has a thickness at said sidewalls that is greater than a thickness at said bottom wall portion; and
a conductive material located on said material stack within said at least one opening.

2. The semiconductor structure of claim 1 wherein said dielectric material is one of SiO₂, a silsesquixoane, a C doped oxide that include atoms of Si, C, O and H, or a thermosetting polyarylene ether.

3. The semiconductor structure of claim 1 wherein said at least one opening is a line opening, a via opening, or a combined line and via opening.

4. The semiconductor structure of claim 1 wherein said diffusion barrier material comprises Ta, TaN, Ti, TiN, Ru, RuN, RuTa, RuTaN, W, WN or any other material that can serve as a barrier to prevent a conductive material from diffusing there through.

5. The semiconductor structure of claim 1 wherein said material stack further comprises a metal seed layer located atop said diffusion barrier material.

6. The semiconductor structure of claim 5 wherein said metal seed layer comprises a conductive metal or metal alloy.

7. The semiconductor structure of claim 6 wherein said metal seed layer comprises Cu, CuAl, CuIr, CuTa, CuRh or TaRu.

8. The semiconductor structure of claim 1 wherein said conductive material comprises polySi, a conductive metal, an alloy comprising at least one conductive metal, a conductive metal silicide or combinations thereof.

9. The semiconductor structure of claim 1 further comprising an additional material stack comprising at least another diffusion barrier material located on sidewalls within said at least one opening between said dielectric material and said material stack having said thickness at said sidewalls that is greater than a thickness at said bottom wall portion.

10. A method of fabricating a semiconductor structure comprising:
providing a dielectric material having at least one opening located therein, said at least one opening including sidewalls that extend and are in contact with a bottom wall portion;
forming a material stack comprising at least a diffusion barrier material within said at least one opening covering said sidewalls and said bottom wall portion, wherein said material stack has a thickness at said sidewalls that is greater than a thickness at said bottom wall portion; and
forming a conductive material on said material stack within said at least one opening.

11. The method of claim 10 wherein said forming said dielectric material having said at least one opening comprises deposition, lithography and etching.

12. The method of claim 10 wherein said forming a material stack comprises an ionization ratio controlled plasma deposition process.

13. The method of claim 12 wherein said ionization ratio controlled plasma deposition process comprises providing a ratio of ionized metal to neutral metal of about 50 or less.

14. The method of claim 13 wherein said ionization ratio controlled plasma deposition process comprises adjusting at least one parameter selected from the group consisting of DC power, AC bias and process pressure.

15. The method of claim 14 wherein said ionization ratio controlled plasma deposition process comprises adjusting said DC power to a value of less than 15 kW.

16. The method of claim 14 wherein said ionization ratio controlled plasma deposition process comprises adjusting said AC bias to a value below 1000 W.

17. The method of claim 14 wherein said ionization ratio controlled plasma deposition process comprises adjusting said process pressure to a value below 10 mT.

18. The method of claim 10 wherein said material stack further comprises a metal seed layer.

19. The method of claim 10 further comprising forming an additional material stack comprising at least a diffusion barrier material prior to forming the material stack having a thickness at said sidewalls that is greater than a thickness at said bottom wall portion.

20. The method of claim 19 wherein said additional material stack is formed by deposition and sputter etching, wherein said deposition comprises a process in which the additional material stack has a thickness at the bottom wall portion that is greater than along the sidewalls.
